(19) United States
(12) Patent Application Publication
(10) Pub. No.: US 2026/0266922 A1
(43) Pub. Date: Sep. 10, 2026

(54) Computer-Implemented Method for Determining a State of Health “SoH” of a High-Voltage Storage Device

(71) Applicant: Bayerische Motoren Werke Aktiengesellschaft, Muenchen (DE)

(72) Inventors: Robin DROOP, Muenchen (DE); Andres JACOME, Muenchen (DE); Florian LIMMER, Gruenwald (DE)

(21) Appl. No.: 19/560,930

(22) Filed: Mar. 9, 2026

(30) Foreign Application Priority Data
Mar. 10, 2025 (DE) 10 2025 108 876.4

(51) Int. Cl. G01R 31/392; G01R 31/367

(52) U.S. Cl. CPC G01R 31/392; G01R 31/367

(57) ABSTRACT

A computer-implemented method for determining a state of health “SoH” of a high-voltage storage device includes obtaining a first estimated variable that is based on at least one parameter of the high-voltage storage device, obtaining at least one second estimated variable that is based on at least one parameter of the high-voltage storage device, checking the plausibility of the obtained estimated variables using a predetermined plausibility-checking algorithm, normalizing the plausible estimated variables, and processing the normalized estimated variables.

### CROSS-REFERENCE TO RELATED APPLICATION

This application claims priority under 35 U.S.C. §119 from European Patent Application No. 10 2025 108 876.4, filed March 10, 2025, the entire disclosure of which is herein expressly incorporated by reference.

### BACKGROUND AND SUMMARY

The present disclosure relates to a computer-implemented method for determining a state of health "SoH" of a high-voltage storage device, having steps of obtaining a first estimated variable that is based on at least one parameter of the high-voltage storage device; obtaining at least one second estimated variable that is based on at least one parameter of the high-voltage storage device; checking the plausibility of the obtained estimated variables using a predetermined plausibility-checking algorithm; normalizing the plausible estimated variables; and processing the normalized estimated variables.

In the case of an SoH estimation of a high-voltage storage device, the state of health of the energy storage device is evaluated. In particular, the SoH value indicates how much of the original energy or capacity of the storage device is still available in comparison to its new state. Currently, the determination of a state of health (SoH) of battery cells in vehicle engineering is mainly based on a single algorithm that is based on an open-circuit-voltage (OCV) look-up estimator. This method, which aims to assign the measured quiescent voltage to an SoH value, was until now considered to be sufficient. However, accuracy limitations are associated with such an OCV look-up estimator, especially with regard to temperature dependence and aging effects.

Lithium iron phosphate (LFP) technology, known for its safety and durability, has a flat voltage curve during charging and discharging, which makes it difficult to accurately determine the SoH, that is to say the state of health, of the battery. For batteries having lithium iron phosphate (LFP) chemistry, a characteristically flat discharge voltage curve may lead to problems when determining the SoH, since minor voltage changes are not able to be clearly assigned to an SoH value. On account of this characteristic, the common SoH estimation method, which is based on the open circuit voltage, is no longer sufficiently precise, which results in inaccurate battery state information. An OCV look-up estimator therefore reaches the limits of its physical performance capability, especially in the case of new cell chemistries such as LFP batteries, for example.

Against this background, it is an object of the present disclosure to improve a method for determining a state of health "SoH" of a high-voltage storage device. In particular, such a method should be improved to the effect of enabling robust and reliable SoH determination.

This object is achieved by a computer-implemented method for determining a state of health "SoH" of a high-voltage storage device having the features disclosed herein. The present disclosure also relates to advantageous developments.

According to a first aspect, a computer-implemented method for determining a state of health "SoH" of a high-voltage storage device is specified, having steps of obtaining a first estimated variable that is based on at least one, in particular physical, parameter of the high-voltage storage device; obtaining at least one second estimated variable that is based on at least one, in particular physical, parameter of the high-voltage storage device; checking the plausibility of the obtained estimated variables using a predetermined plausibility-checking algorithm; normalizing the plausible estimated variables; and processing the normalized estimated variables on the basis of a decision-making algorithm in such a way that at least one SoH value is determined for the high-voltage storage device.

By way of example, in this case an estimated variable may characterize a loss of capacity, an internal resistance of the high-voltage storage device, an efficiency of the high-voltage storage device and/or a self-discharging process of the high-voltage storage device. The proposed method may be used, using decision logic, to combine and/or to weight such estimated variables, which are in particular determined on the basis of different diagnostic methods for determining SoH-relevant data, in order to enable improved SoH determination.

A high-voltage storage device is in particular an energy storage device or a drive rechargeable battery for a motor vehicle, which has a plurality of battery cells, in particular LFP battery cells, arranged in one and/or more cell packs or cell assemblies. In this case, a housing of the high-voltage storage device defines an interior space in which the battery cells are accommodated or arranged. Recording apparatuses and/or determination apparatuses may be arranged in and/or on the high-voltage storage device or on the battery cells, wherein each of the recording apparatuses may be arranged at a predetermined measurement point and may be configured to record at least one physical variable of the or on the high-voltage storage device or devices.

In this case, an estimated variable is in particular a value of a physical variable that is recorded at the high-voltage storage device, in particular using at least one recording apparatus. By way of example, such a physical variable may be a capacity, an electrical resistance and/or a voltage of the high-voltage storage device or at a predetermined measurement point or recording apparatus of the high-voltage storage device.

In some exemplary embodiments, the estimated variable may be determined as a parameter on the basis of an experimental or measurement-based determination method in dependence on at least one recorded measured value or recording signal. For this purpose, for example, an internal resistance of the high-voltage storage device may be measured or recorded and kept available as an estimated variable, since the internal resistance typically increases with increasing aging. In other exemplary embodiments, an open-circuit voltage may be measured or recorded after a quiescent phase of the high-voltage storage device. This recorded open-circuit voltage (OCV) is a function of the state of charge (SoC) and may be compared with a reference SoC-OCV curve to determine the estimated variable.

In some exemplary embodiments, the estimated variable may be determined as a parameter on the basis of an model-based determination method, in particular by a determination apparatus, in dependence on at least one recorded measured value or recording signal. Such a model-based determination method may be based on mathematical models and/or at least one algorithm. In this case, in particular at least one electrical and/or thermal measured value may be used as an influencing variable to calculate the estimated variable by a model such as an equivalent circuit model (ECM) and/or an electrochemical simulation model, for example.

In some exemplary embodiments, the estimated variable may be determined in dependence on operating data of the high-voltage storage device. In this case, for example, a number of charging cycles may be determined and compared, and/or compared with reference databases by a degradation model.

The obtained first estimated variable and the obtained second estimated variable, as well as each further obtained estimated variable, are determined in particular by different determination methods, for example those described above, in order to allow a broad combination variance.

The present disclosure is now based, inter alia, on the concept of combining a plurality of determination methods, which are suitable for determining an estimated variable relating to an SoH of the high-voltage storage device, in order to benefit from a reliable determination of a single, combined SoH value, in particular for high-voltage storage devices with batteries based on lithium iron phosphate (LFP) technology.

For this purpose, it is proposed to determine at least two estimated variables based on different determination methods and to provide them for a decision-making algorithm. The plausibility of these at least two different estimated variables is checked using a predetermined plausibility-checking algorithm in order to check the provided estimated variables for their validity and/or correctness before they are further processed. For this purpose, the plausibility-checking algorithm may perform a check for logical consistency, for completeness and/or for inconsistencies, for example. In a further step, the plausible, that is to say remaining, estimated variables are normalized in order to bring them into a standardized form so that a decision-making algorithm may process the data or estimated variables in particular in an efficient and/or consistent manner. In this case, for example, values may be scaled and/or unit steps may be eliminated in order to avoid distortions caused by numerical values or scales of different magnitudes.

In a further step, the normalized estimated variables are processed on the basis of a decision-making algorithm, with the result that an SoH value for the high-voltage storage device is determined in response to the obtained estimated variables. Such a decision-making algorithm may include, for example, a set of rules, heuristics, control flow logic, state logic, rule-based logic and/or inference logic, by which the estimated variables are analyzed, fused and/or aggregated. This allows different determination methods to be combined in order to combine specific advantages and therefore be able to achieve robust results under different conditions and/or application scenarios. These combined estimated variables are output by the decision-making algorithm in the form of the SoH value. By way of example, such an SoH value may be output as a maximum range and/or as a percentage, wherein a value of 100% corresponds to a new high-voltage storage device. By way of example, this SoH value may be used to output a service life forecast and/or to enable safety monitoring with regard to aging-related safety risks, such as the risk of overheating and/or short-circuiting, for example.

In one embodiment, the plausibility of the obtained estimated variable is checked on the basis of an estimated variable history of the respective estimated variable. In this case, an estimated variable history comprises previously recorded and stored estimated variables and may be used as a reference for comparisons, analyses and/or forecasts. This allows the obtained estimate variable or variables to be validated in the sense of a longitudinal plausibility check in order to enable improved data quality.

In one embodiment, the plausibility of the obtained estimated variables is checked on the basis of further estimated variables, in particular those obtained at the relevant point in time. In this case, for example, it is possible to carry out a cross-plausibility check with other estimated variables or sensor values in order to be able to verify their credibility and/or correctness.

In one embodiment, the decision-making algorithm comprises a weighting of the estimated variables, an averaging of the estimated variables and/or a total error calculation. By way of example, a weighting of the estimated variables may comprise a Bayes filter, weighted averages and/or fuzzy logic. By way of example, averaging may comprise the formation of an arithmetic average, an exponentially smoothed average and/or a median estimation. By way of example, a total error calculation may comprise an error propagation (propagation of uncertainty), a root mean square error (RMSE) rating and/or a Kalman filter. As a result, the plurality of obtained estimated variables may be linked in such a way that an improved determination of an SoH value may be made possible from a plurality of estimated variables that are in particular inaccurate and/or incomplete.

In one embodiment, an estimated variable is determined in dependence on a capacity-estimating algorithm. A capacity-estimating algorithm is in particular a mathematical method for determining the remaining usable capacity of the high-voltage storage device, which may calculate or determine a capacity under real operating conditions, for example on the basis of measured values such as voltage, current and/or temperature, as well as historical data of the high-voltage storage device.

In one embodiment, an estimated variable is based on a capacity measurement at the high-voltage storage device. In this case, for example, a capacity that is able to be drawn may be recorded or measured by a recording apparatus or a sensor under defined charging and discharging conditions of the high-voltage storage device, and a currently recorded capacity may be compared with an original capacity of the high-voltage storage device.

In one embodiment, an estimated variable is determined by an aging model of the high-voltage storage device. In this case, for example, battery models may be combined with voltage, current and temperature data, in particular in the form of an equivalent circuit model (ECM).

In one embodiment, the at least one SoH value comprises an associated quality indicator in relation to the respective estimated variable. By way of example, such a quality indicator may be a quality value that is stored together with a measured value for a parameter of the high-voltage storage device and/or an estimated variable in a signal tuple estimated variable history. By way of example, the quality indicator may be used to quantify a measurement accuracy, a data quality, a sensor state and/or a standard deviation in order to be able to take these into consideration when processing the estimated variables.

In one embodiment, the method comprises the further step of adding the at least one obtained estimated variable, the SoH value and/or the quality indicator to an estimated variable history. This allows recorded and/or specific values to be documented in order to be able to track developments, to validate a new estimated variable and/or to derive trends.

In one embodiment, the decision-making algorithm is based on a machine learning model. In order to provide the machine learning model, a machine learning model is first trained with recorded data or particular estimated variables, which are determined, or have been determined, by different determination methods and other structured input data or values, such as a number of battery cells and/or dimensions of the high-voltage storage device, for example. These data are recorded and in particular come from the high-voltage storage device or identical or similar high-voltage storage devices. In addition, further relevant data sources may be integrated, such as historical measured values, environmental conditions and/or operation-specific parameters, for example. This combination enables comprehensive analysis and may improve the quality of the model.

Before the training, data may be preprocessed to make recorded or provided raw data usable for the model. In this case, the data or values may be cleaned up by removing incorrect and/or incomplete values. The data or values may then be normalized and/or scaled, for example by way of min-max scaling or z-standardization, to make them comparable. In addition, feature engineering may be used, in which features such as averages, trends and/or differences to other measurements, are extracted from the recorded data or particular estimated variables. By way of example, in the case of time-dependent data, a time-series transformation may be carried out in order to make the data usable for forecast models.

In a next step, the actual model training is able to take place, wherein the processed data may be divided into training and test data, for example in a ratio of 80:20. By way of example, an algorithm used for the model may be linear regression, random forest, and/or gradient boosting, in particular for non-linear relationships. In some exemplary embodiments, a recurrent neural network (RNN) or a long short-term memory (LSTM) network may be used. During the training, the machine learning model or the decision-making algorithm adjusts its parameters to minimize the errors between the predictions or the particular SoH values and actual values. A gradient descent or other optimization methods may be used for this purpose, for example.

After the training, the decision-making algorithm may be subjected to an evaluation and optimization. By way of example, various metrics such as a mean square error (MSE) or the R² value may be calculated to determine a prediction accuracy. By way of example, if the model does not operate satisfactorily, hyperparameter tuning may be performed, in which model parameters of the decision-making algorithm, such as learning rate, number of neurons or tree depth, are optimized. After successful evaluation, the model may be transferred to real operation, where it is continuously fed with new data or estimated variables. Using a feedback loop, the decision-making algorithm may be regularly retrained with current data or estimated variables and/or SoH values in order to further improve its accuracy and robustness. As a result, a service life forecast and/or safety monitoring may be provided for the high-voltage storage device by the SoH value.

Further advantages and possible uses of the present disclosure will emerge from the description that follows in conjunction with the figures.

Other objects, advantages and novel features of the present disclosure will become apparent from the following detailed description of one or more preferred embodiments when considered in conjunction with the accompanying drawings.

### BRIEF DESCRIPTION OF THE DRAWINGS

FIG. 1 shows a schematic illustration of a high-voltage storage device with a control apparatus for determining a state of health "SoH" of a high-voltage storage device according to an exemplary embodiment of the present disclosure.

FIG. 2 shows a schematic flowchart of a computer-implemented method for determining a state of health "SoH" of a high-voltage storage device according to an exemplary embodiment of the present disclosure.

### DETAILED DESCRIPTION OF THE DRAWINGS

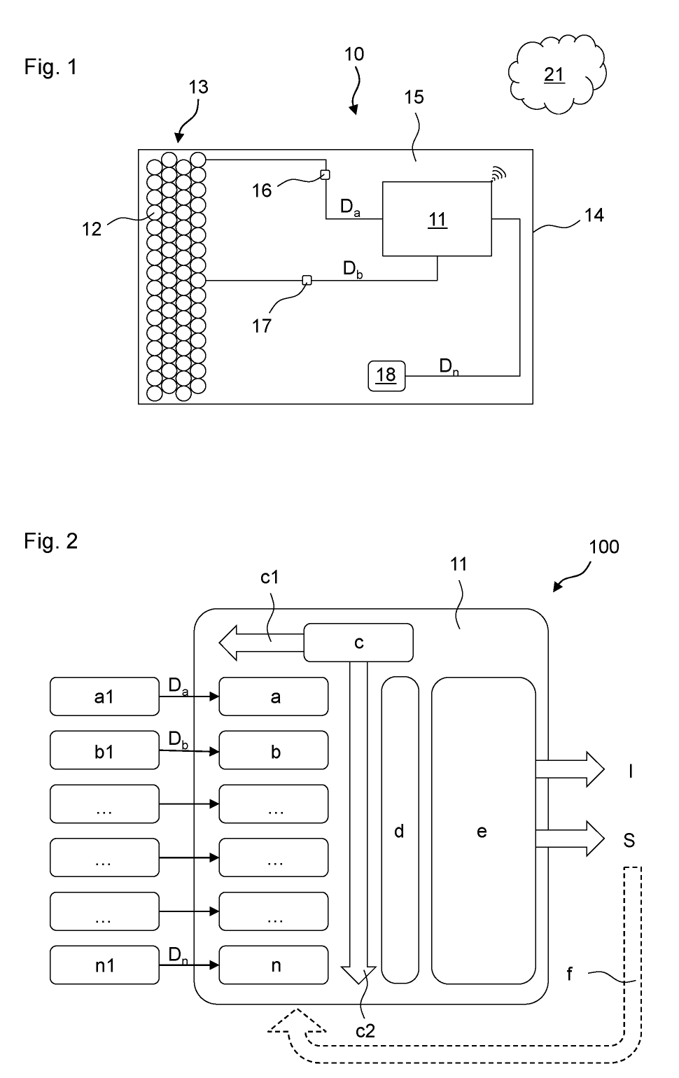

FIG. 1 shows a schematic illustration of a high-voltage storage device 10 with a control apparatus 11 that is configured to carry out a method for determining a state of health "SoH" of a high-voltage storage device 10 according to an exemplary embodiment of the present disclosure.

The high-voltage storage device 10 has a plurality of lithium iron phosphate battery cells 12, which are arranged in a cell pack 13 (only partially illustrated in this case) in an interior space 15 of the housing 14 that is surrounded by a housing 14 of the high-voltage storage device 10. In the present exemplary embodiment, a first recording apparatus 16 and a second recording apparatus 17 are arranged in the interior space 15 and on the battery cells 12. The first recording apparatus 16 is configured to record a capacity of the high-voltage storage device 10 and to provide a first estimated variable Da, on the basis of the capacity, as the first parameter of the high-voltage storage device 10 at the control apparatus 11. The second recording apparatus 17 is configured to record an internal resistance of the high-voltage storage device 10 and to provide a second estimated variable Db, on the basis of the internal resistance, as the second parameter of the high-voltage storage device 10 at the control apparatus 11. A determination apparatus 18 is configured to determine a third estimated variable Dₙ on the basis of an aging model of the high-voltage storage device 10 and to provide same at the control apparatus 11. In some embodiments, the determination apparatus 18 may be part of the control apparatus 11 or the third estimated variable Dₙ may be determined by the control apparatus 11.

The control apparatus 11 is configured to obtain the estimated variables Dₐ to Dₙ, to check the plausibility of the obtained estimated variables Dₐ to Dₙ using a predetermined plausibility-checking algorithm, and to normalize the plausible estimated variables Da to Dn. In addition, the control apparatus 11 is configured to process by a decision-making algorithm, which may comprise a machine learning model, in such a way that at least one SoH value is determined. By way of example, an energy management system is able to be adjusted, in particular by adjusting charging and discharging strategies, and/or a residual value determination, in particular with regard to an evaluation in the second-life range, may be made possible by the SoH value or on the basis of the SoH value.

FIG. 2 shows a schematic flowchart of a computer-implemented method 100 for determining a state of health "SoH" of the exemplary high-voltage storage device 10 from FIG. 1 according to an exemplary embodiment of the present disclosure.

In a step a1, the first recording apparatus 16 may be used to record a capacity of the high-voltage storage device 10 and to determine a first estimated variable Dₐ, on the basis of the capacity, as the first parameter of the high-voltage storage device 10, and to provide the first estimated variable at the control apparatus 11. In a step b1, the first recording apparatus 17 may be used to record an internal resistance of the high-voltage storage device 10 and to determine a second estimated variable D_{b}, on the basis of the internal resistance, as the second parameter of the high-voltage storage device 10, and to provide the second estimated variable at the control apparatus 11. In a step n1, the determination apparatus 18 may be used to provide a third estimated variable Dₙ at the control apparatus 11 on the basis of an aging model of the high-voltage storage device 10, wherein an age and/or a number of usage cycles may, for example, be a third parameter of the high-voltage storage device 10.

The first estimated variable Dₐis obtained in a step a, the second estimated variable Db is obtained in a step b and the third estimated variable Dₙ is obtained in a step n. Of course, as indicated graphically, any desired number of estimated variables Dₐ to Dₙmay be obtained, wherein the estimated variables Dₐ to Dₙ are preferably based on different determination methods a1 to n1. In a step c, the plausibility of the obtained estimated variables Dₐ to Dₙ is checked using a predetermined plausibility-checking algorithm. In this case, for example, it is possible to carry out a longitudinal plausibility check c1 on the basis of an estimated variable history of the respective estimated variables Dₐto Dₙand/or a cross-plausibility check c2 on the basis of further obtained estimated variables Dₐ to Dₙ.

In a step d, the plausible estimated variables Dₐ, D_{b}, Dₙ are normalized. In a further step e, the normalized estimated variables Dₐ, D_{b}, Dₙ are processed on the basis of a decision-making algorithm in such a way that at least one SoH value S is determined for the high-voltage storage device 10 or for in particular all battery cells separately, and may be output. The decision-making algorithm may be based on a machine learning model, which has been trained with a training data set comprising empirically provided estimated variables Dₐ, D_{b}, Dₙ and/ or particular SoH values S. This allows different estimated variables Dₐ, D_{b}, Dₙ in relation to the high-voltage storage device 10 to be combined with one another, in order to use a reliable determination of an SoH value S in particular for high-voltage storage devices 10 with batteries based on lithium iron phosphate (LFP) technology. In some exemplary embodiments, the SoH value S may comprise an associated quality indicator I in particular in relation to a respective estimated variable Dₐ, D_{b}, Dₙ. By way of example, such a quality indicator I may quantify a data quality and/or a standard deviation. Of course, further estimated variables D may be recorded, obtained, the plausibility thereof may be checked, and they may be normalized, processed, etc., without departing from the scope of the present disclosure.

In an optional step f, the obtained estimated variables Dₐ,D_{b}, Dₙ and/ or particular SoH values S may be added to an estimated variable history and/ or to the decision-making algorithm in order to improve a determination of the SoH value S.

The foregoing disclosure has been set forth merely to illustrate the present disclosure and is not intended to be limiting. Since modifications of the disclosed embodiments incorporating the spirit and substance of the present disclosure may occur to persons skilled in the art, the present disclosure should be construed to include everything within the scope of the appended claims and equivalents thereof.

### LIST OF REFERENCE SIGNS

10 High-voltage storage device

11 Control apparatus

12 Battery cells

13 Cell pack

14 Housing

15 Interior space

16 First recording apparatus

17 Second recording apparatus

18 Determination apparatus

a-f Steps

DₐFirst estimated variable

D_{b}Second estimated variable

Dₙ Third estimated variable

S SoH value

What is claimed is:

1. A computer-implemented method for determining a state of health “SoH” of a high-voltage storage device, the method comprising:
obtaining a first estimated variable that is based on at least one parameter of the high-voltage storage device;
obtaining at least one second estimated variable that is based on at least one parameter of the high-voltage storage device;
checking plausibility of the first estimated variable and the at least one second estimated variable using a predetermined plausibility-checking algorithm to determine plausible estimated variables;
normalizing the plausible estimated variables; and
processing the normalized plausible estimated variables on a basis of a decision-making algorithm in such a way that at least one SoH value is determined for the high-voltage storage device.

2. The computer-implemented method according to claim 1, comprising:
checking the plausibility of the first estimated variable and the at least one second estimated variable based on a diagnostic information history of the respective estimated variable.

3. The computer-implemented method according to claim 1, comprising:
checking the plausibility of the first estimated variable and the at least one second estimated variable based on further obtained estimated variables.

4. The computer-implemented method according to claim 1,
wherein the decision-making algorithm comprises weighting, averaging, and/or calculating a total error of the first estimated variable and the at least one second estimated variable.

5. The computer-implemented method according to claim 1, comprising:
determining at least one of the first estimated variable and/or the at least one second estimated variable in dependence on a capacity-estimating algorithm.

6. The computer-implemented method according to claim 1,
wherein at least one of the first estimated variable and/or the at least one second estimated variable is based on a capacity measurement at the high-voltage storage device.

7. The computer-implemented method according to claim 1, comprising:
determining at least one of the first estimated variable and/or the at least one second estimated variable by an aging model of the high-voltage storage device.

8. The computer-implemented method according to claim 1,
wherein the at least one SoH value comprises an associated quality indicator in relation to a respective one of the first estimated variable and/or the at least one second estimated variable.

9. The computer-implemented method according to claim 1, comprising:
adding at least one of the first estimated variable and/or the at least one second estimated variable and/or the SoH value to an estimated variable history.

10. The computer-implemented method according to claim 1,
wherein the decision-making algorithm is based on a machine learning model.
